(19) United States
(12) Patent Application Publication
(10) Pub. No.: US 2022/0239855 A1
(43) Pub. Date: Jul. 28, 2022

(54) IMAGE SENSORS HAVING READOUT CIRCUITRY WITH A SWITCHED CAPACITOR LOW-PASS FILTER

(71) Applicant: SEMICONDUCTOR COMPONENTS INDUSTRIES, LLC, Phoenix, AZ (US)

(72) Inventor: Peter SPIESSENS, Werchter (BE)

(73) Assignee: SEMICONDUCTOR COMPONENTS INDUSTRIES, LLC, Phoenix, AZ (US)

(21) Appl. No.: 17/248,515

(22) Filed: Jan. 28, 2021

(51) Int. Cl. H04N 5/378; H01L 27/146; H04N 5/357

(52) U.S. Cl. CPC H04N 5/378; H04N 5/357; H01L 27/14603; H01L 27/14609

(57) ABSTRACT

An image sensor may include an array of imaging pixels arranged in rows and columns. Each column of imaging pixels may be coupled to a respective column output line that is used to read out samples from the imaging pixels. Each column output line may be coupled to a respective switched capacitor low-pass filter that is used to filter out high-frequency noise during readout. The switched capacitor includes a capacitor, a first transistor that is coupled between the capacitor and the column output line, and a second transistor that is coupled between the capacitor and an additional capacitor. The first and second transistors are repeatedly, alternatingly asserted at a frequency that is selected based on a target cutoff frequency for the low-pass filter.

### BACKGROUND

Image sensors are commonly used in electronic devices such as cellular telephones, cameras, and computers to capture images. In a typical arrangement, an electronic device is provided with an array of image pixels arranged in pixel rows and pixel columns. Each image pixel in the array includes a photodiode that is coupled to a floating diffusion region via a transfer gate. Row control circuitry is coupled to each pixel row for resetting, initiating charge transfer, or selectively activating a particular row of pixels for readout. Column circuitry is coupled to each pixel column for reading out pixel signals from the image pixels.

The image pixel array is read out on a row-by-row basis. Readout noise associated with the pixel source follower transistors and/or power supply noise may adversely impact the sensor performance. Some techniques for mitigating readout noise may undesirably require increasing the frame time for the image sensor.

It is within this context that the embodiments described herein arise.

### BRIEF DESCRIPTION OF THE DRAWINGS

FIG. 1 is a diagram of an illustrative electronic device having an image sensor in accordance with an embodiment.

FIG. 2 is a diagram of an illustrative pixel array and associated row and column control circuitry for reading out image signals from an image sensor in accordance with an embodiment.

FIG. 3 is a diagram of an illustrative image sensor with readout circuitry including a switched capacitor low-pass filter in accordance with an embodiment.

FIG. 4 is a timing diagram showing illustrative waveforms for the control signals of the switched capacitor low-pass filter of FIG. 3 in accordance with an embodiment.

### DETAILED DESCRIPTION

Embodiments of the present technology relate to image sensors. It will be recognized by one skilled in the art that the present exemplary embodiments may be practiced without some or all of these specific details. In other instances, well-known operations have not been described in detail in order not to unnecessarily obscure the present embodiments.

Electronic devices such as digital cameras, computers, cellular telephones, and other electronic devices may include image sensors that gather incoming light to capture an image. The image sensors may include arrays of pixels. The pixels in the image sensors may include photosensitive elements such as photodiodes that convert the incoming light into image signals. Image sensors may have any number of pixels (e.g., hundreds or thousands or more). A typical image sensor may, for example, have hundreds or thousands or millions of pixels (e.g., megapixels). Image sensors may include control circuitry such as circuitry for operating the pixels and readout circuitry for reading out image signals corresponding to the electric charge generated by the photosensitive elements.

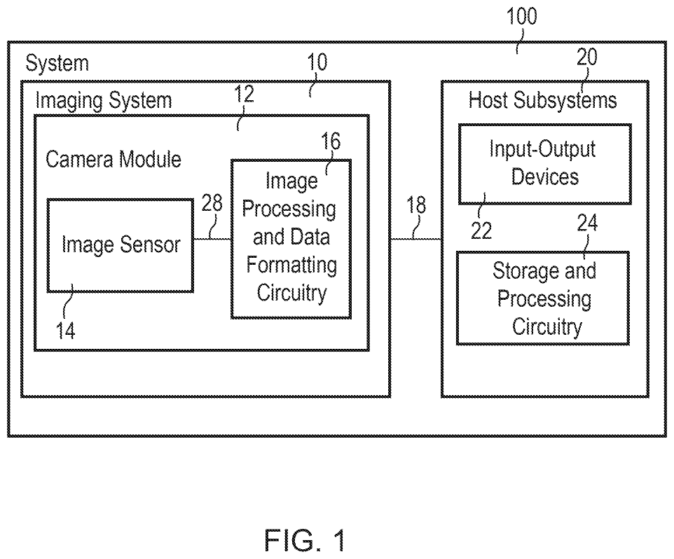

FIG. 1 is a diagram of an illustrative imaging and response system including an imaging system that uses an image sensor to capture images. System 100 of FIG. 1 may be an electronic device such as a camera, a cellular telephone, a video camera, or other electronic device that captures digital image data, may be a vehicle safety system (e.g., an active braking system or other vehicle safety system), or may be a surveillance system.

As shown in FIG. 1, system 100 may include an imaging system such as imaging system 10 and host subsystems such as host subsystem 20. Imaging system 10 may include camera module 12. Camera module 12 may include one or more image sensors 14 and one or more lenses.

Each image sensor in camera module 12 may be identical or there may be different types of image sensors in a given image sensor array integrated circuit. During image capture operations, each lens may focus light onto an associated image sensor 14. Image sensor 14 may include photosensitive elements (i.e., image sensor pixels) that convert the light into digital data. Image sensors may have any number of pixels (e.g., hundreds, thousands, millions, or more). A typical image sensor may, for example, have millions of pixels (e.g., megapixels). As examples, image sensor 14 may further include bias circuitry (e.g., source follower load circuits), sample and hold circuitry, correlated double sampling (CDS) circuitry, amplifier circuitry, analog-to-digital converter circuitry, data output circuitry, memory (e.g., buffer circuitry), address circuitry, etc.

Still and video image data from camera sensor 14 may be provided to image processing and data formatting circuitry 16 via path 28. Image processing and data formatting circuitry 16 may be used to perform image processing functions such as data formatting, adjusting white balance and exposure, implementing video image stabilization, face detection, etc. Image processing and data formatting circuitry 16 may also be used to compress raw camera image files if desired (e.g., to Joint Photographic Experts Group or JPEG format). In a typical arrangement, which is sometimes referred to as a system on chip (SoC) arrangement, camera sensor 14 and image processing and data formatting circuitry 16 are implemented on a common semiconductor substrate (e.g., a common silicon image sensor integrated circuit die). If desired, camera sensor 14 and image processing circuitry 16 may be formed on separate semiconductor substrates. For example, camera sensor 14 and image processing circuitry 16 may be formed on separate substrates that have been stacked.

Imaging system 10 (e.g., image processing and data formatting circuitry 16) may convey acquired image data to host subsystem 20 over path 18. Host subsystem 20 may include processing software for detecting objects in images, detecting motion of objects between image frames, determining distances to objects in images, filtering or otherwise processing images provided by imaging system 10.

If desired, system 100 may provide a user with numerous high-level functions. In a computer or advanced cellular telephone, for example, a user may be provided with the ability to run user applications. To implement these functions, host subsystem 20 of system 100 may have input-output devices 22 such as keypads, input-output ports, joysticks, and displays and storage and processing circuitry 24. Storage and processing circuitry 24 may include volatile and nonvolatile memory (e.g., random-access memory, flash memory, hard drives, solid-state drives, etc.). Storage and processing circuitry 24 may also include microprocessors, microcontrollers, digital signal processors, application specific integrated circuits, etc.

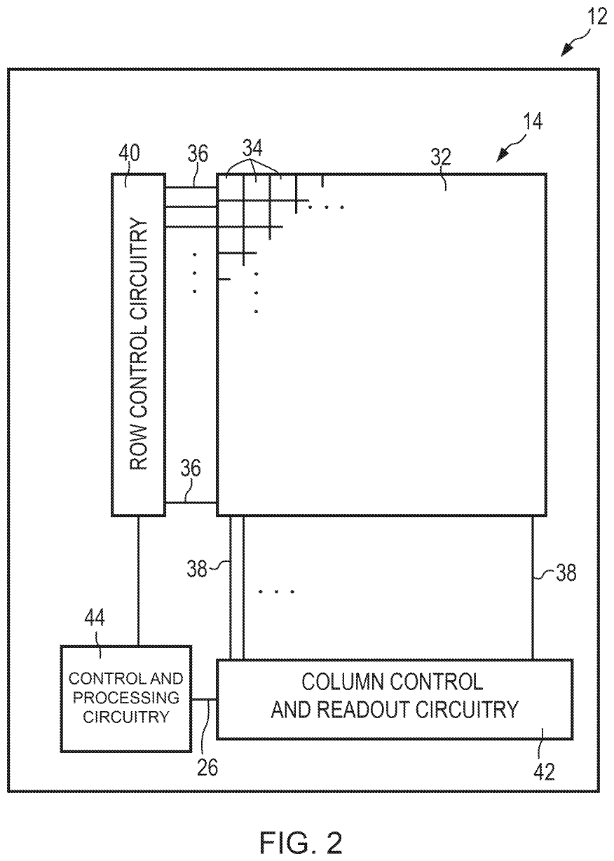

An example of an arrangement of image sensor 14 of FIG. 1 is shown in FIG. 2. As shown in FIG. 2, image sensor 14 may include control and processing circuitry 44. Control and processing circuitry 44 (sometimes referred to as control and processing logic) may sometimes be considered part of image processing and data formatting circuitry 16 in FIG. 1. Image sensor 14 may include a pixel array such as array 32 of pixels 34 (sometimes referred to herein as image sensor pixels, imaging pixels, or image pixels). Control and processing circuitry 44 may be coupled to row control circuitry 40 via control path 27 and may be coupled to column control and readout circuits 42 via data path 26.

Row control circuitry 40 may receive row addresses from control and processing circuitry 44 and may supply corresponding row control signals to image pixels 34 over control paths 36 (e.g., pixel reset control signals, charge transfer control signals, blooming control signals, row select control signals, dual conversion gain control signals, or any other desired pixel control signals).

Column control and readout circuitry 42 may be coupled to the columns of pixel array 32 via one or more conductive lines such as column lines 38. Column lines 38 may be coupled to each column of image pixels 34 in image pixel array 32 (e.g., each column of pixels may be coupled to a corresponding column line 38). Column lines 38 may be used for reading out image signals from image pixels 34 and for supplying bias signals (e.g., bias currents or bias voltages) to image pixels 34. During image pixel readout operations, a pixel row in image pixel array 32 may be selected using row driver circuitry 40 and image data associated with image pixels 34 of that pixel row may be read out by column readout circuitry 42 on column lines 38. Column readout circuitry 42 may include column circuitry such as column amplifiers for amplifying signals read out from array 32, sample and hold circuitry for sampling and storing signals read out from array 32, analog-to-digital converter circuits for converting read out analog signals to corresponding digital signals, and column memory for storing the read out signals and any other desired data. Column control and readout circuitry 42 may output digital pixel readout values to control and processing logic 44 over line 26.

Array 32 may have any number of rows and columns. In general, the size of array 32 and the number of rows and columns in array 32 will depend on the particular implementation of image sensor 14. While rows and columns are generally described herein as being horizontal and vertical, respectively, rows and columns may refer to any grid-like structure (e.g., features described herein as rows may be arranged vertically and features described herein as columns may be arranged horizontally).

Pixel array 32 may be provided with a color filter array having multiple color filter elements which allows a single image sensor to sample light of different colors. As an example, image sensor pixels such as the image pixels in array 32 may be provided with a color filter array which allows a single image sensor to sample red, green, and blue (RGB) light using corresponding red, green, and blue image sensor pixels arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another suitable example, the green pixels in a Bayer pattern are replaced by broadband image pixels having broadband color filter elements (e.g., clear color filter elements, yellow color filter elements, etc.). These examples are merely illustrative and, in general, color filter elements of any desired color and in any desired pattern may be formed over any desired number of image pixels 34.

If desired, array 32 may be part of a stacked-die arrangement in which pixels 34 of array 32 are split between two or more stacked substrates. In such an arrangement, each of the pixels 34 in the array 32 may be split between the two dies at any desired node within the pixel. As an example, a node such as the floating diffusion node may be formed across two dies. Pixel circuitry that includes the photodiode and the circuitry coupled between the photodiode and the desired node (such as the floating diffusion node, in the present example) may be formed on a first die, and the remaining pixel circuitry may be formed on a second die. The desired node may be formed on (i.e., as a part of) a coupling structure (such as a conductive pad, a micro-pad, a conductive interconnect structure, or a conductive via) that connects the two dies. Before the two dies are bonded, the coupling structure may have a first portion on the first die and may have a second portion on the second die. The first die and the second die may be bonded to each other such that first portion of the coupling structure and the second portion of the coupling structure are bonded together and are electrically coupled. If desired, the first and second portions of the coupling structure may be compression bonded to each other. However, this is merely illustrative. If desired, the first and second portions of the coupling structures formed on the respective first and second dies may be bonded together using any metal-to-metal bonding technique, such as soldering or welding.

As mentioned above, the desired node in the pixel circuit that is split across the two dies may be a floating diffusion node. Alternatively, the desired node in the pixel circuit that is split across the two dies may be the node between a floating diffusion region and the gate of a source follower transistor (i.e., the floating diffusion node may be formed on the first die on which the photodiode is formed, while the coupling structure may connect the floating diffusion node to the source follower transistor on the second die), the node between a floating diffusion region and a source-drain node of a transfer transistor (i.e., the floating diffusion node may be formed on the second die on which the photodiode is not located), the node between a source-drain node of a source follower transistor and a row select transistor, or any other desired node of the pixel circuit.

In general, array 32, row control circuitry 40, and column control and readout circuitry 42 may be split between two or more stacked substrates. In one example, array 32 may be formed in a first substrate and row control circuitry 40 and column control and readout circuitry 42 may be formed in a second substrate. In another example, array 32 may be split between first and second substrates (using one of the pixel splitting schemes described above) and row control circuitry 40 and column control and readout circuitry 42 may be formed in a third substrate.

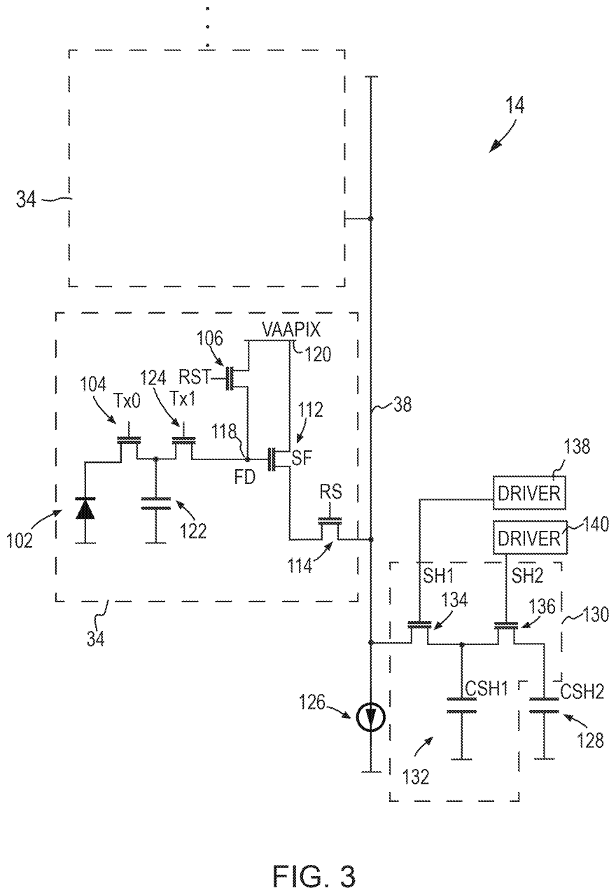

The amount of read noise associated with the image sensor is a key performance indicator. In general, it is desirable to reduce the read noise for the image sensor. One way to reduce image sensor read noise is to incorporate a switched capacitor low-pass filter in the readout path. An image sensor of this type is shown in FIG. 3.

As shown in FIG. 3, image sensor 14 includes imaging pixels 34 coupled to a column output line 38. Each image pixel 34 may include a photosensitive element 102 (e.g., a photodiode). Photosensitive element 102 has a first terminal that is coupled to ground. The second terminal of photosensitive element 102 is coupled to transfer transistor 104. Transfer transistor 104 is coupled to charge storage region 122. Charge storage region 122 may be a storage diode, a storage capacitor, a storage gate, etc. An additional transfer transistor 124 may be coupled between charge storage region 122 and floating diffusion (FD) region 118. A reset transistor 106 may be coupled between floating diffusion region 118 and voltage supply 120. Floating diffusion region 118 may be a doped semiconductor region (e.g., a region in a silicon substrate that is doped by ion implantation, impurity diffusion, or other doping process). Floating diffusion 118 has an associated capacitance.

Source-follower transistor 112 has a gate terminal coupled to floating diffusion region 118. Source-follower transistor 112 also has a first source-drain terminal coupled to voltage supply 120. Voltage supply 120 may provide a power supply voltage (V_{AAPIX}). In this application, each transistor is illustrated as having three terminals: a source, a drain, and a gate. The source and drain terminals of each transistor may be changed depending on how the transistors are biased and the type of transistor used. For the sake of simplicity, the source and drain terminals are referred to herein as source-drain terminals or simply terminals. A second source-drain terminal of source-follower transistor 112 is coupled to column output line 38 through row select transistor 114.

A gate terminal of transfer transistor 104 receives control signal TX0. A gate terminal of transfer transistor 124 receives control signal TX1. A gate terminal of reset transistor 106 receives control signal RST. A gate terminal of row select transistor 114 receives control signal RS. Control signals TX0, TX1, RST, and RS may be provided by row control circuitry (e.g., row control circuitry 40 in FIG. 2) over control paths (e.g., control paths 36 in FIG. 2).

As shown in FIG. 3, the output of each pixel in a given column may be coupled to column output line 38. In other words, the row select transistor in each pixel may be coupled to column output line 38 (sometimes referred to as column line 38, output line 38, etc.). While the row select transistor for a given row of pixels is asserted, that row's output may be provided on column output line 38.

Column output line 38 is coupled to a current supply 126. Column output line is additionally coupled to a capacitor 128 (sometimes referred to as a sample and hold capacitor or output capacitor). Samples from one of the pixels in a column may be sampled onto capacitor 128 during readout operations. To reduce readout noise, a switched capacitor low-pass filter 130 is interposed between output line 38 and capacitor 128. Switched capacitor low-pass filter 130 includes an additional capacitor 132, a first transistor 134, and a second transistor 136. First transistor 134 has a first terminal that is coupled to column output line 38 and a second terminal that is coupled to capacitor 132. Second transistor 136 has a first terminal that is coupled to capacitor 132 and a second terminal that is coupled to capacitor 128.

It should be noted that capacitor 128 may sometimes be referred to as being part of switched capacitor low-pass filter 130.

A gate terminal of transistor 134 receives control signal SH1. A gate terminal of transistor 136 receives control signal SH2. Control signal SH1 may be provided to transistor 134 by a respective driver 138 whereas control signal SH2 may be provided to transistor 136 by a respective driver 140. Drivers 138 and 140 may be considered part of row control circuitry 40 and/or column control and readout circuitry 42. Drivers 138 and 140 may be referred to as control circuitry. Capacitor 128 and switched capacitor low-pass filter 130 may be considered part of column control and readout circuitry 42.

Every column of pixels in the image sensor may have a corresponding capacitor 128 and switched capacitor low-pass filter 130. The same control signals SH1 and SH2 may be provided to the switched capacitor low-pass filter of every column such that the readout circuit of each column is operated in parallel.

During operation of the imaging pixel 34, charge generated by photodiode 102 in response to incident light may be transferred to floating diffusion 118. One or more samples associated with the imaging pixel may be obtained in a given image frame. As one example, a reset sample and a signal sample may be obtained from imaging pixel 34. The reset sample may be obtained after floating diffusion region 118 is reset to a reset voltage. Then, charge may be transferred to floating diffusion region 118 and a signal sample may be obtained. The difference between the reset signal and the sample signal may subsequently be determined in a correlated double sampling scheme.

During sampling, row select transistor 114 is asserted. Charge proportional to the amount of charge on floating diffusion 118 is stored at capacitor 128. This may be referred to as a sample and hold procedure. Once the charge is stored at capacitor 128, additional readout steps may be performed (e.g., analog-to-digital conversion, storing the corresponding digital signal in memory, etc.).

Without switched capacitor low-pass filter 130, the samples would be stored directly on capacitor 128 without passing through a filter. However, in this type of scheme, there may be noise associated with source follower transistor 112 and bias voltage 120. To reduce the amount of noise present, time-domain oversampling methods like correlated multiple sampling or direct pixel output delta-sigma analog-to-digital conversion may be used. However, these schemes require increasing the readout time and therefore (undesirably) increasing the frame time for each image frame. Alternatively, increasing the size of capacitor 128 may improve readout noise. However, capacitor 128 occupies valuable space on the image sensor and increasing the size of each capacitor 128 may not be feasible or practical.

The switched capacitor low-pass filter of FIG. 3 mitigates readout noise without substantive adverse effects on frame time or capacitor area. The low-pass filter removes high-frequency noise caused by source follower transistor 112 and/or power supply noise. During readout operations, control signals SH1 and SH2 may be pulsed in an alternating fashion. For example, SH1 may be high while SH2 is low. Then the signals are switched such that SH1 is low while SH2 is high. This process may be repeated many times throughout the sampling process. With this type of operation, the switched capacitor effectively serves as a resistor that provides low-pass filtering.

The cutoff frequency (ω_{-3 dB}) of the switched capacitor low-pass filter is provided by the formula ω_{-3 dB}=f_{SH}*(CSH1/CSH2), where f_{SH} is the frequency at which control signals SH1 and SH2 are pulsed, CSH1 is the capacitance of capacitor 132, and CSH2 is the capacitance of capacitance 128.

There are numerous advantages afforded by the switched capacitor low-pass filter arrangement of FIG. 3. First, the cutoff frequency is a function of the ratio of capacitances CSH1 and CSH2 (as opposed to a function of a single capacitance). This means that the filter is robust to temperature and manufacturing variations that may impact capacitors 132 and 128. In general, these types of variations will impact capacitors 132 and 128 similarly. Therefore, the ratio of the capacitances will be minimally impacted by temperature and manufacturing variations.

Additionally, the cutoff frequency may be tuned in real time simply by updating the clock frequency f_{SH}. The cutoff frequency is proportional to f_{SH}. Therefore, by adjusting f_{SH} the cutoff frequency of the low-pass filter may be adjusted. This is useful because the same switched capacitor low-pass filter circuit may be incorporated into many different image sensors having different applications. A simple clock frequency adjustment then allows for the low-pass filter circuit to function sufficiently well in all of the image sensors with different applications. Additionally, if the target noise frequency changes, the clock frequency may be adjusted to optimize the cutoff frequency for the low-pass filter.

Yet another advantage of the arrangement of FIG. 3 is that capacitor 132 in low-pass filter 130 may be very small. Therefore, the low-pass filter does not occupy excessive space in the image sensor. Capacitance CSH2 may be greater than CSH1, at least three times greater than CSH1, at least five times greater than CSH1, at least ten times greater than CSH1, at least fifteen times greater than CSH1, at least twenty times greater than CSH1, at least fifty times greater than CSH1, between three and fifty times greater than CSH1, etc.

It should be noted that the specific arrangement of pixels 34 in FIG. 3 is merely illustrative. In general, a switched capacitor low-pass filter of the type shown in FIG. 3 may be included in an image sensor having imaging pixels of any type. The imaging pixels may have different or additional transistors (e.g., overflow transistors, dual conversion gain transistors, transfer transistors, etc.), different or additional charge storage regions (e.g., storage capacitors, storage gates, storage diodes, etc.), different or additional photosensitive areas, or any other desired components.

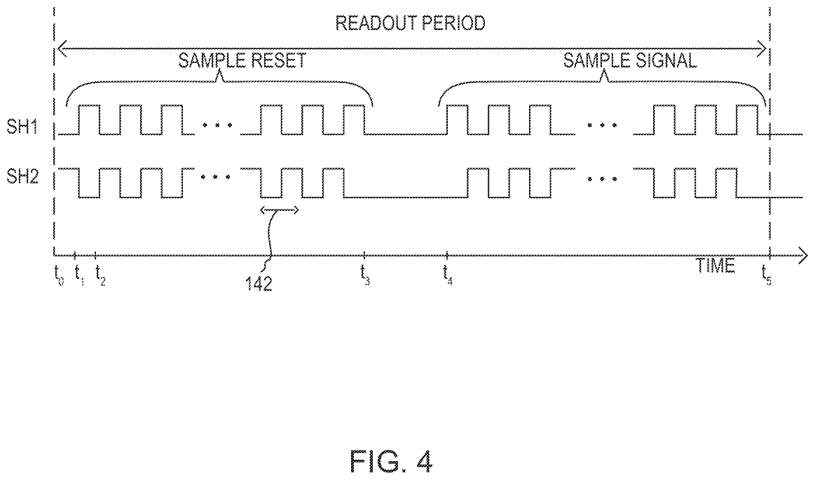

FIG. 4 is a timing diagram showing illustrative waveforms for control signals SH1 and SH2 during operation of low-pass filter 130. In the example of FIG. 4, two separate signals are sampled during the readout period. First the reset signal (e.g., the reset voltage of the floating diffusion region) is sampled between t₀ and t₃. Subsequently, the sample signal (e.g., with the charge from the photosensitive area) is sampled between t₄ and t₅.

During each sampling period, SH1 and SH2 are asserted in a non-overlapping manner. As shown, at t₀ SH1 is low while SH2 is high. At t₁, SH1 is raised high and SH2 is dropped low. At t₂, SH1 is again dropped low while SH2 is again raised high. This pattern may repeat throughout the sampling periods. Each cycle (of the control signals being high for a period of time and low for a period of time) has a duration 142. Duration 142 is equal to one divided by the clock frequency (e.g., T=1/f_{SH}, where T is the cycle duration and f_{SH} is the clock frequency). During each cycle, each control signal may be low for a slightly longer period of time than the control signal is high (to ensure that the signals are not high at the same time).

The clock frequency f_{SH} may have any desired value (e.g., to target the high frequency noise for the specific image sensor). As an example, f_{SH} may be greater than or equal to 1 MHz, greater than or equal to 10 MHz, greater than or equal to 25 MHz, greater than or equal to 50 MHz, greater than or equal to 100 MHz, greater than or equal to 250 MHz, less than or equal to 1 MHz, less than or equal to 10 MHz, less than or equal to 25 MHz, less than or equal to 50 MHz, less than or equal to 100 MHz, less than or equal to 250 MHz, between (inclusive) 1 MHz and 100 MHz, between (inclusive) 10 MHz and 100 MHz, between (inclusive) 1 MHz and 250 MHz, between (inclusive) 25 MHz and 75 MHz, between (inclusive) 5 MHz and 15 MHz, etc.

If desired, additional capacitors and transistors may be included in the low-pass filter. Having a higher order low-pass filter of this type may improve filtering at the expense of additional required capacitor area.

The foregoing is merely illustrative and various modifications can be made to the described embodiments. The foregoing embodiments may be implemented individually or in any combination.

What is claimed is:

1. An image sensor, comprising:
an array of imaging pixels;
a column output line coupled to a column of the imaging pixels; and
a switched capacitor low-pass filter coupled to the column output line.

2. The image sensor defined in claim 1, further comprising:
a capacitor, wherein the switched capacitor low-pass filter is coupled between the capacitor and the column output line.

3. The image sensor defined in claim 1, wherein the capacitor is a first capacitor and wherein the switched capacitor low-pass filter comprises a second capacitor.

4. The image sensor defined in claim 3, wherein a capacitance of the first capacitor is greater than a capacitance of the second capacitor.

5. The image sensor defined in claim 3, wherein a capacitance of the first capacitor is at least ten times greater than a capacitance of the second capacitor.

6. The image sensor defined in claim 3, wherein the switched capacitor low-pass filter comprises a first transistor that is coupled between the second capacitor and the column output line.

7. The image sensor defined in claim 6, wherein the switched capacitor low-pass filter comprises a second transistor that is coupled between the second capacitor and the first capacitor.

8. The image sensor defined in claim 7, wherein the first and second transistors are configured to be repeatedly, alternatingly asserted during a readout period.

9. The image sensor defined in claim 7, wherein the first and second transistors are configured to be repeatedly asserted in a non-overlapping manner.

10. The image sensor defined in claim 9, wherein the first and second transistors are configured to be repeatedly asserted in the non-overlapping manner at a frequency and wherein the frequency is greater than or equal to 1 MHz.

11. The image sensor defined in claim 9, wherein the first and second transistors are configured to be repeatedly asserted in the non-overlapping manner at a frequency and wherein the frequency is greater than or equal to 10 MHz.

12. The image sensor defined in claim 9, wherein the first and second transistors are configured to be repeatedly asserted in the non-overlapping manner at a frequency and wherein the frequency is between 1 MHz and 100 MHz.

13. An image sensor, comprising:
an array of imaging pixels;
a column output line coupled to a column of the imaging pixels;
a first capacitor;
a first transistor that is coupled between the first capacitor and the column output line;
a second capacitor; and
a second transistor that is coupled between the first and second capacitors, wherein the first and second transistors are configured to be repeatedly, alternatingly asserted during a readout period.

14. The image sensor defined in claim 13, wherein a capacitance of the second capacitor is greater than a capacitance of the first capacitor.

15. The image sensor defined in claim 13, wherein the first and second transistors are configured to be repeatedly, alternatingly asserted during the readout period at a frequency that is greater than or equal to 1 MHz.

16. The image sensor defined in claim 13, wherein the first and second transistors are configured to be repeatedly, alternatingly asserted during the readout period at a frequency that is between 1 MHz and 100 MHz.

17. An image sensor, comprising:
an array of imaging pixels;
a plurality of column lines, wherein each column line is configured to receive outputs from a respective column of the imaging pixels; and
a plurality of switched capacitor low-pass filters, wherein each column line is coupled to a respective switched capacitor low-pass filter.

18. The image sensor defined in claim 17, wherein each switched capacitor low-pass filter comprises:
a first capacitor;
a first transistor that is coupled between the first capacitor and the respective column output line; and
a second transistor that is coupled to the first capacitor.

19. The image sensor defined in claim 18, further comprising:
control circuitry configured to alternate asserting the first and second transistors of each switched capacitor low-pass filter.

20. The image sensor defined in claim 19, wherein the control circuitry is configured to alternate asserting the first and second transistors of each switched capacitor low-pass filter at a frequency that is greater than 1 MHz.
